(19) United States
(12) Patent Application Publication
(10) Pub. No.: US 2025/0270998 A1
(43) Pub. Date: Aug. 28, 2025

(54) FAN ASSEMBLY AND SERVER

(71) Applicants: INVENTEC (PUDONG) TECHNOLOGY CORPORATION, Shanghai (CN); INVENTEC CORPORATION, Taipei City (TW)

(72) Inventors: Hui-Ming TSAI, Taipei City (TW); Huang-Chi CHANG, Taipei City (TW); Shou-Yuan SHIH, Taipei City (TW)

(73) Assignees: INVENTEC (PUDONG) TECHNOLOGY CORPORATION, Shanghai (CN); INVENTEC CORPORATION, Taipei City (TW)

(21) Appl. No.: 18/673,180

(22) Filed: May 23, 2024

(30) Foreign Application Priority Data
Feb. 27, 2024 (CN) 202410218997.1

(51) Int. Cl. F04D 19/00; F04D 29/60; F04D 29/64

(52) U.S. Cl. CPC F04D 19/002; F04D 29/541; F04D 29/601; F04D 29/646; F04D 29/667; F04D 29/002

(57) ABSTRACT

A server includes a chassis and a fan assembly. The fan assembly includes a fan, a first flow guiding plate and a second flow guiding plate. The fan is disposed in the chassis. The first flow guiding plate and the second flow guiding plate are disposed beside the fan, and are arranged along a central axis of the fan. The first flow guiding plate includes a plurality of first flow guiding holes. The second flow guiding plate includes a plurality of second flow guiding holes. The plurality of first flow guiding holes and the plurality of second flow guiding holes are misaligned with one another.

### CROSS-REFERENCE TO RELATED APPLICATIONS

This non-provisional application claims priority under 35 U.S.C. § 119 (a) on Patent Application No(s). 202410218997.1 filed in China, on Feb. 27, 2024, the entire contents of which are hereby incorporated by reference.

### BACKGROUND OF THE INVENTION

### Technical Field of the Invention

The invention relates to a fan assembly and a server, more particularly to a fan assembly and a server including flow guiding plates.

### Description of the Related Art

With the rapid development of technology, the computation performance of an electronic device such as a server and an expansion cards has been improved significantly, while a large amount of heat has been generated by the electronic device. In order to prevent the electronic device from being damaged due to high temperature, a fan is generally used to cool the electronic device, so that the electronic device can operate within an adequate temperature range.

Conventionally, to effectively cool the electronic device with high computing performance, the rotation speed of the fan is increased. However, the higher the rotation speed of the fan is, the louder the noise is generated, thereby causing a physical or psychological impact on users. Thus, some manufacturers install sound-absorbing cottons on the fan or limit the rotation speed of the fan to reduce the noise generated by the fan during operation. However, it may take a lot of time to install the sound-absorbing cottons, which causes inconvenience in installation. On the other hand, the cooling capability of the fan may be reduced due to the limitation of the rotation speed thereof. In this way, an air baffle may be required to be additionally installed to guide the air blown by the fan, which also causes inconvenience in installation. Therefore, maintaining the cooling capability of the fan while reducing the noise generated by the fan during operation is one of the problems required to be addressed.

### SUMMARY OF THE INVENTION

The invention provides a fan assembly and a server so as to maintain the cooling capability of the fan while reducing the noise generated by the fan during operation.

One embodiment of the invention provides a fan assembly including a fan, a first flow guiding plate and a second flow guiding plate. The first flow guiding plate and the second flow guiding plate are disposed beside the fan, and are arranged along a central axis of the fan. The first flow guiding plate includes a plurality of first flow guiding holes. The second flow guiding plate includes a plurality of second flow guiding holes. The plurality of first flow guiding holes and the plurality of second flow guiding holes are misaligned with one another.

Another embodiment of the invention provides a server including a chassis and a fan assembly. The fan assembly includes a fan, a first flow guiding plate and a second flow guiding plate. The fan is disposed in the chassis. The first flow guiding plate and the second flow guiding plate are disposed beside the fan, and are arranged along a central axis of the fan. The first flow guiding plate includes a plurality of first flow guiding holes. The second flow guiding plate includes a plurality of second flow guiding holes. The plurality of first flow guiding holes and the plurality of second flow guiding holes are misaligned with one another.

According to the fan assembly and the server disclosed by the above embodiments, the server includes the flow guiding plates, and the flow guiding holes of the flow guiding plates are misaligned with one another. Thus, the airflow blown by the fan can be guided to form a laminar flow. That is, the airflow can be guided to be stratified smoothly, so that a mixture of the airflow can be reduced, thereby reducing vortices generated by the airflow. Therefore, the noise generated by the vortices can be reduced without limiting the rotation speed of the fan, and thus the cooling capability of the fan can be maintained. In addition, the loss of the sound energy can also be increased via the misalignment of the flow guiding holes so as to prevent the noise from being transmitted outward. Accordingly, the cooling capability of the fan can be maintained while reducing the noise generated by the fan during operation.

### BRIEF DESCRIPTION OF THE DRAWINGS

The invention will become more fully understood from the detailed description given herein below and the accompanying drawings which are given by way of illustration only and thus are not limitative of the invention and wherein:

FIG. 1 is a perspective view of a server in accordance with one embodiment of the invention;

FIG. 2 is a perspective view of a fan assembly of the server in FIG. 1;

FIG. 3 is an exploded view of the fan assembly of the server in FIG. 1;

FIG. 4 is a plane view of a flow guiding member of the server in FIG. 1;

FIG. 5 is a partially enlarged plane view of the flow guiding member of the server in FIG. 1;

FIG. 6 is a partially enlarged and cross-sectional view of the flow guiding member of the server in FIG. 1; and

FIG. 7 is a cross-sectional view of the server in FIG. 1.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In addition, the terms used in the invention, such as technical and scientific terms, have its own meanings and can be comprehended by those skilled in the art, unless the terms are additionally defined in the invention. That is, the terms used in the following paragraphs should be read on the meaning commonly used in the related fields and will not be overly explained, unless the terms have a specific meaning in the invention.

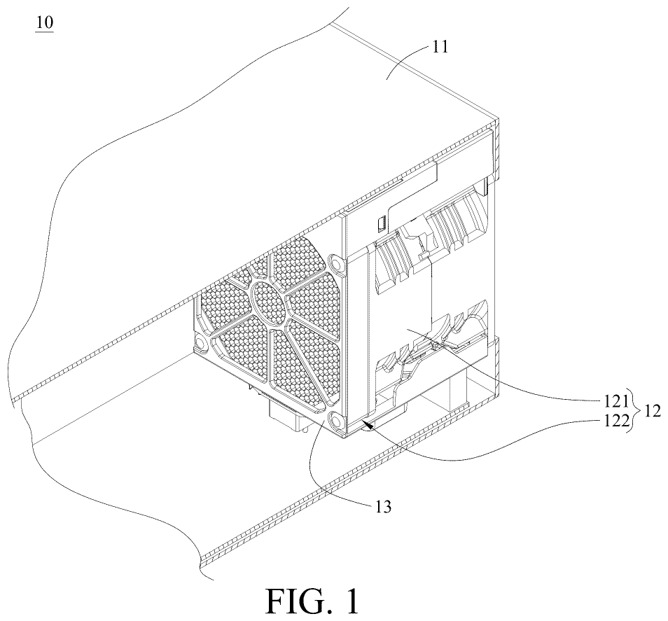

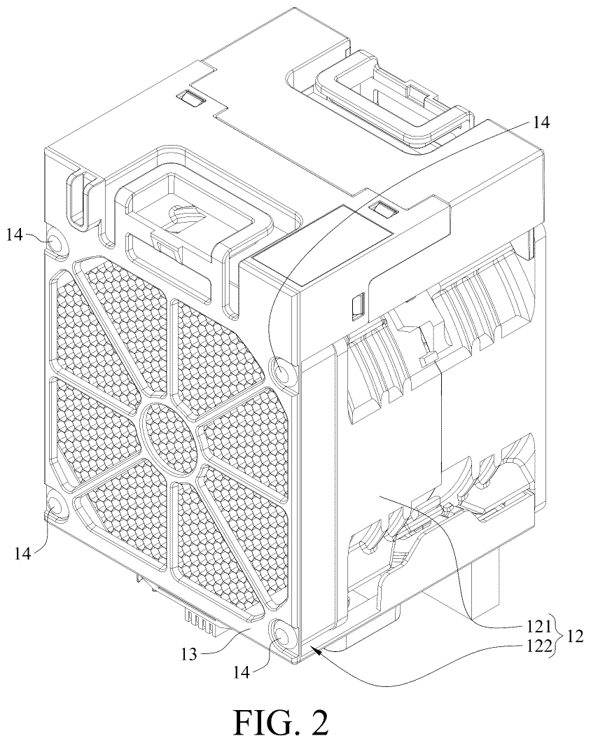

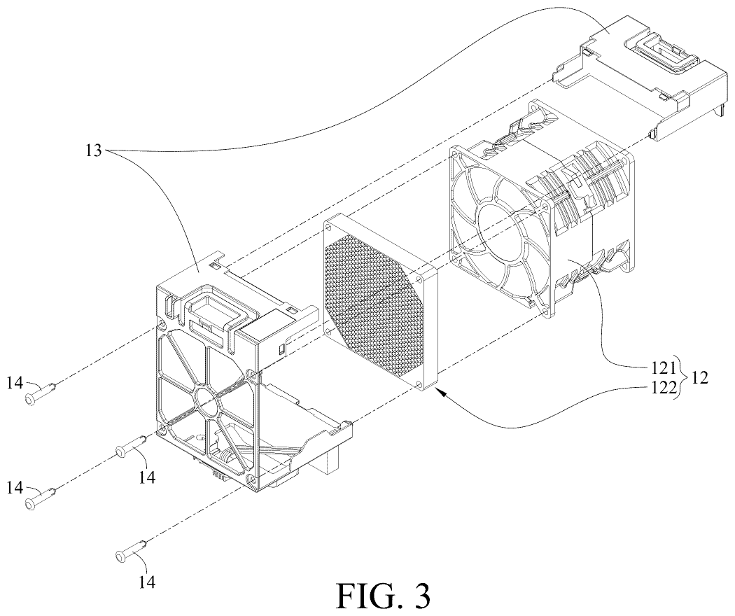

Please refer to FIG. 1 to FIG. 3, where FIG. 1 is a perspective view of a server 10 in accordance with one embodiment of the invention, FIG. 2 is a perspective view of a fan assembly 12 of the server 10 in FIG. 1, and FIG. 3 is an exploded view of the fan assembly 12 of the server 10 in FIG. 1.

In this embodiment, the server 10 includes a chassis 11 and a fan assembly 12. The fan assembly 12 includes a fan 121 and a flow guiding member 122. The fan 121 is disposed in the chassis 11, and is configured to blow an airflow to cool, for example, a heat source (not shown) disposed in the server 10, but the invention is not limited thereto.

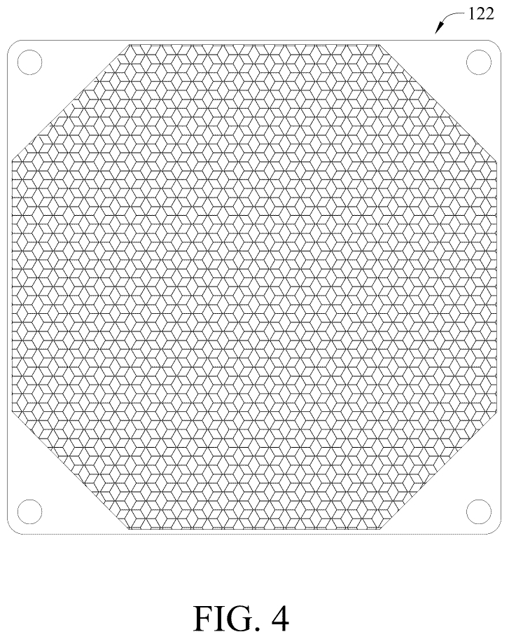

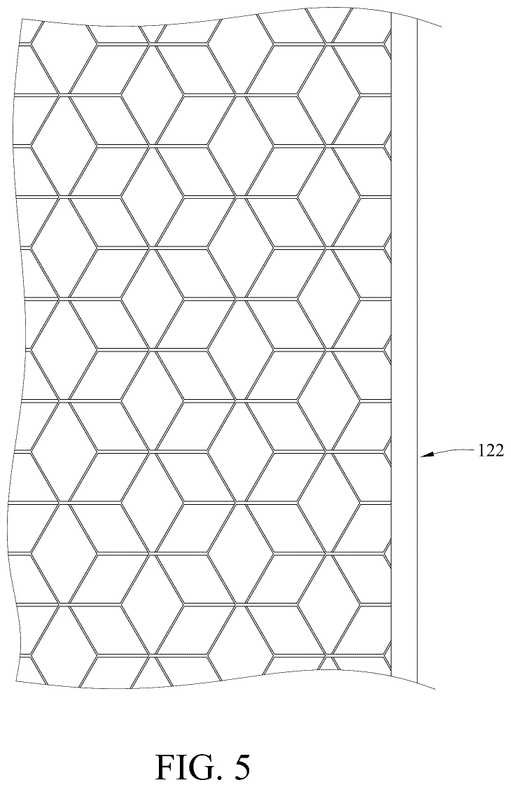

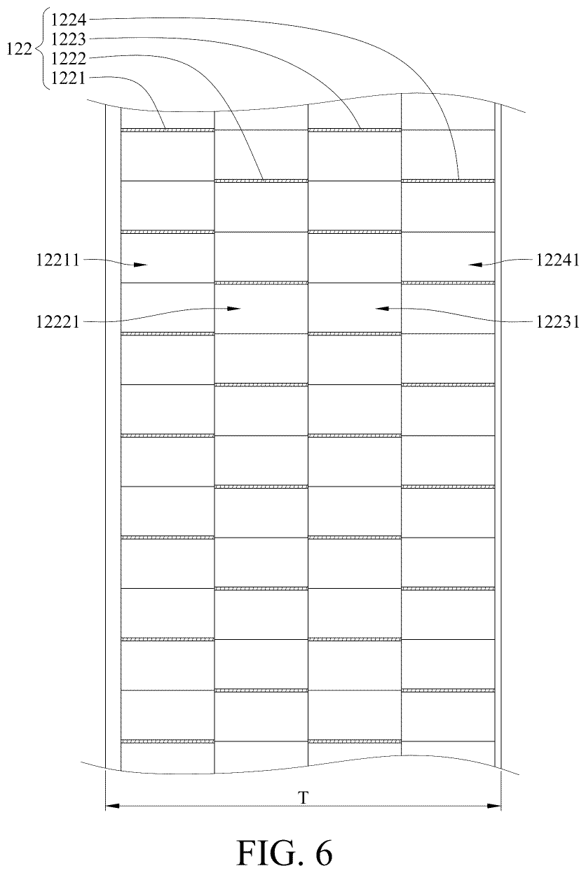

Please refer to FIG. 1 to FIG. 6, where FIG. 4 is a plane view of the flow guiding member 122 of the server 10 in FIG. 1, FIG. 5 is a partially enlarged plane view of the flow guiding member 122 of the server 10 in FIG. 1, and FIG. 6 is a partially enlarged and cross-sectional view of the flow guiding member 122 of the server 10 in FIG. 1.

The flow guiding member 122 includes a first flow guiding plate 1221, a second flow guiding plate 1222, a third flow guiding plate 1223 and a fourth flow guiding plate 1224. The flow guiding plates 1221 to 1224 are disposed beside the fan 121, and are arranged along a central axis of the fan 121. In detail, the flow guiding plates 1221 to 1224 are disposed on the same side of the fan 121, and the flow guiding plates 1221 to 1224 are spaced apart from the fan 121 by different distances. That is, the flow guiding plates 1221 to 1224 are arranged side by side on the same side of the fan 121. For example, the flow guiding plates 1221 to 1224 are arranged side by side on the side of the fan 121 where an air inlet is located. In addition, a thickness T of the flow guiding member 122 is, for example, 12.5 millimeters. That is, an overall thickness T of the flow guiding plates 1221 to 1224 is, for example, 12.5 millimeters.

The first flow guiding plate 1221 includes a plurality of first flow guiding holes 12211. The second flow guiding plate 1222 includes a plurality of second flow guiding holes 12221. The third flow guiding plate 1223 includes a plurality of third flow guiding holes 12231. The fourth flow guiding plate 1224 includes a plurality of fourth flow guiding holes 12241. The flow guiding holes 12211 to 12241 are misaligned with one another. In detail, the flow guiding holes 12211 to 12241 are not coaxial. That is, central axes of the flow guiding holes 12211 to 12241 are different. In addition, the flow guiding holes 12211 to 12241 have, for example, the same shape. For example, the flow guiding holes 12211 to 12241 are honeycomb-shaped.

In this embodiment, the server 10 may further include a mounting cage 13 and a plurality of fasteners 14. The fasteners 14 are, for example, screws. The fan 121 and the flow guiding plates 1221 to 1224 are fixed to the mounting cage 13 via the fasteners 14.

In this embodiment, the server 10 includes the flow guiding plates 1221 to 1224, and the flow guiding holes 12211 to 12241 of the flow guiding plates 1221 to 1224 are misaligned with one another. Thus, the airflow blown by the fan 121 can be guided to form a laminar flow. That is, the airflow can be guided to be stratified smoothly, so that a mixture of the airflow can be reduced, thereby reducing vortices generated by the airflow. Therefore, the noise generated by the vortices can be reduced without limiting the rotation speed of the fan 121, and thus the cooling capability of the fan 121 can be maintained. In addition, the loss of the sound energy can also be increased via the misalignment of the flow guiding holes 12211 to 12241 so as to prevent the noise from being transmitted outward. Accordingly, the cooling capability of the fan 121 can be maintained while reducing the noise generated by the fan 121 during operation.

In this embodiment, the flow guiding plates 1221 to 1224 are arranged side by side on the side of the fan 121 where the air inlet is located, but the invention is not limited thereto. In other embodiments, the flow guiding plates may be arranged side by side on the side of the fan where an air outlet is located.

In this embodiment, the flow guiding plates 1221 to 1224 are disposed on the same side of the fan 121, but the invention is not limited thereto. In other embodiments, the flow guiding plates may be disposed on the different sides of the fan, respectively. That is, the flow guiding plates may be disposed on the sides of the fan where the air inlet and the air outlet are located, respectively.

In this embodiment, the fan assembly 12 includes four flow guiding plates 1221 to 1224, and the thickness T of the flow guiding member 122 is 12.5 millimeters, but the invention is not limited thereto. In other embodiments, the fan assembly may include less than four or more than four flow guiding plates, and the thickness of the flow guiding member may also be, for example, 12.5 millimeters.

In this embodiment, the flow guiding holes 12211 to 12241 are not coaxial, but the invention is not limited thereto. In other embodiments, as long as the flow guiding holes are misaligned, the flow guiding holes may be coaxial.

In this embodiment, the flow guiding holes 12211 to 12241 have the same shape, but the invention is not limited thereto. In other embodiments, the flow guiding holes may have different shapes.

In this embodiment, the flow guiding holes 12211 to 12241 are honeycomb-shaped, but the invention is not limited thereto. In other embodiments, the flow guiding holes may be in other shapes.

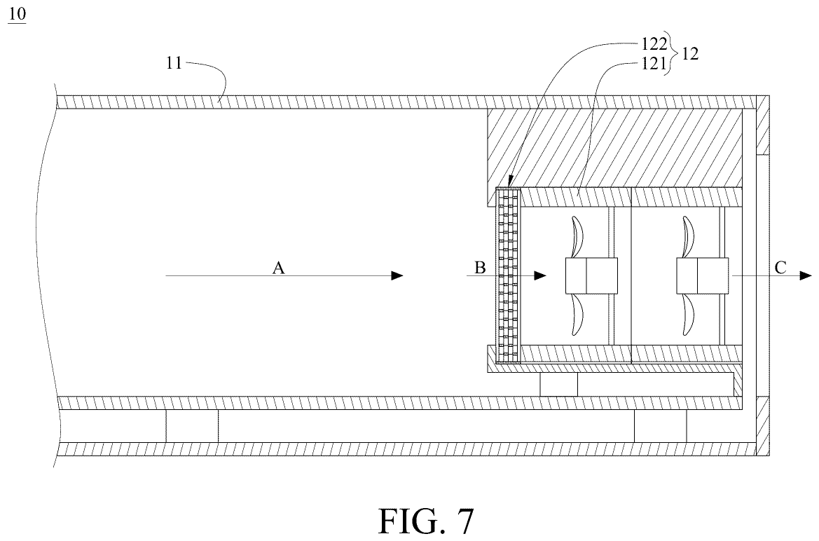

Please refer to FIG. 6 and FIG. 7, where FIG. 7 is a cross-sectional view of the server 10 in FIG. 1. In this embodiment, the heat source (not shown) can generate heat during operation. When the fan 121 is turned on, the fan 121 blow an airflow configured to cool the heat source by absorbing the heat generated by the heat source and flowing out of the server 10.

In detail, firstly, when the fan 121 is turned on, the fan 121 blows an airflow configured to absorb the heat generated by the server and flowing towards the flow guiding plates 1221 to 1224 along a direction A. Then, the airflow blown by the fan 121 flows through the flow guiding holes 12211 to 12241 of the flow guiding plates 1221 to 1224 along a direction B. Then, the airflow flowing through the flow guiding holes 12211 to 12241 flows out of the server 10 along a direction C. Since the airflow is guided to be stratified smoothly via the misaligned flow guiding holes 12211 to 12241, the generation of the vortices can be reduced so as to reduce the noise.

According to the fan assembly and the server disclosed by the above embodiments, the server includes the flow guiding plates, and the flow guiding holes of the flow guiding plates are misaligned with one another. Thus, the airflow blown by the fan can be guided to form a laminar flow. That is, the airflow can be guided to be stratified smoothly, so that a mixture of the airflow can be reduced, thereby reducing vortices generated by the airflow. Therefore, the noise generated by the vortices can be reduced without limiting the rotation speed of the fan, and thus the cooling capability of the fan can be maintained. In addition, the loss of the sound energy can also be increased via the misalignment of the flow guiding holes so as to prevent the noise from being transmitted outward. Accordingly, the cooling capability of the fan can be maintained while reducing the noise generated by the fan during operation.

In this embodiment, the server of the invention can be applied to artificial intelligence (AI) computing, edge computing, and can also be used as a 5G server, a cloud server or a Vehicles Internet server.

It will be apparent to those skilled in the art that various modifications and variations can be made to the invention. It is intended that the specification and examples be considered as exemplary embodiments only, with the scope of the invention being indicated by the following claims.

What is claimed is:

1. A fan assembly, comprising:
a fan; and
a first flow guiding plate and a second flow guiding plate, disposed beside the fan and arranged along a central axis of the fan, wherein the first flow guiding plate comprises a plurality of first flow guiding holes, the second flow guiding plate comprises a plurality of second flow guiding holes, and the plurality of first flow guiding holes and the plurality of second flow guiding holes are misaligned with one another.

2. The fan assembly according to claim 1, wherein the plurality of first flow guiding holes and the plurality of second flow guiding holes are not coaxial.

3. The fan assembly according to claim 2, wherein the plurality of first flow guiding holes and the plurality of second flow guiding holes have an identical shape.

4. The fan assembly according to claim 1, wherein the first flow guiding plate and the second flow guiding plate are disposed on a side of the fan, and the first flow guiding plate and the second flow guiding plate are spaced apart from the fan by different distances.

5. The fan assembly according to claim 1, wherein the first flow guiding plate and the second flow guiding plate are located on different sides of the fan, respectively.

6. The fan assembly according to claim 1, further comprising a mounting cage, wherein the fan, the first flow guiding plate and the second flow guiding plate are mounted in the mounting cage.

7. The fan assembly according to claim 6, further comprising a plurality of fasteners, wherein the fan, the first flow guiding plate and the second flow guiding plate are fixed to the mounting cage via the plurality of fasteners.

8. The fan assembly according to claim 1, wherein the first flow guiding plate and the second flow guiding plate have an overall thickness of 12.5 millimeters.

9. A server, comprising:
a chassis; and
a fan assembly, comprising:
a fan, disposed in the chassis; and
a first flow guiding plate and a second flow guiding plate, disposed beside the fan and arranged along a central axis of the fan, wherein the first flow guiding plate comprises a plurality of first flow guiding holes, the second flow guiding plate comprises a plurality of second flow guiding holes, and the plurality of first flow guiding holes and the plurality of second flow guiding holes are misaligned with one another.

10. The server according to claim 9, wherein the plurality of first flow guiding holes and the plurality of second flow guiding holes are not coaxial.
